(19) United States
(12) Patent Application Publication
(10) Pub. No.: US 2013/0171743 A1
(43) Pub. Date: Jul. 4, 2013

(54) MAGNETIC DEVICE AND METHOD OF MANUFACTURING THE SAME

(71) Applicants: Jang-eun Lee, Suwon-si (KR); Soon-oh Park, Suwon-si (KR); Sang-hwan Park, Hwaseong-si (KR); Hee-ju Shin, Yongin-si (KR)

(72) Inventors: Jang-eun Lee, Suwon-si (KR); Soon-oh Park, Suwon-si (KR); Sang-hwan Park, Hwaseong-si (KR); Hee-ju Shin, Yongin-si (KR)

(21) Appl. No.: 13/729,147

(22) Filed: Dec. 28, 2012

(30) Foreign Application Priority Data
Dec. 30, 2011 (KR) 10-2011-0147416

(51) Int. Cl. H01L 43/12

(52) U.S. Cl. CPC H01L 43/12
USPC 438/3

(57) ABSTRACT

A magnetic device and a method of manufacturing the same. In the method, a lower magnetic layer, an insulation layer, and an upper magnetic layer are sequentially formed on a substrate. An upper magnetic layer pattern is formed by patterning the upper magnetic layer until an upper surface of the insulation layer is exposed. An isolation layer pattern is formed from portions of the insulation layer and the lower magnetic layer by performing an oxidation process on the exposed upper surface of the insulation layer, and an insulation layer pattern and a lower magnetic layer pattern are formed from portions of the insulation layer and the lower magnetic layer, where the isolation layer pattern is not formed.

### CROSS-REFERENCE TO RELATED APPLICATIONS

This application claims the benefit of Korean Patent Application No. 10-2011-0147416, filed on Dec. 30, 2011, in the Korean Intellectual Property Office, the disclosure of which is incorporated herein in its entirety by reference.

### BACKGROUND

The inventive concept relates to a magnetic device and a method of manufacturing the same, and more particularly, to a magnetic device that uses magnetic resistance and a method of manufacturing the same.

A magnetic memory device is a non-volatile memory device that uses magnetization to represent stored data. One such magnetic memory device is a spin transfer torque (STT) STT-RAM which uses a spin transfer torque (STT) phenomenon. That is, when a current, spins of which are polarized in one direction, is allowed to flow through the magnetic memory device, the magnetization direction of the magnetic layers changes due to the spin transfer of electrons. STT-RAM includes a magnetic tunnel junction pattern that includes an insulation layer interposed between two magnetic layers. The resistance value of the magnetic tunnel junction pattern may vary according to the magnetization direction of the two magnetic layers. Data may be programmed or erased using a difference between the resistance values. A magnetic memory device that uses the STT phenomenon is advantageous when a degree of integration is high, since a minimum current required is small as the size of cell is reduced. However, as the size of the cell is reduced, patterning of the magnetic tunnel junction pattern becomes more difficult.

### SUMMARY

The inventive concept provides a magnetic device having a high integration density.

The inventive concept also provides a method of manufacturing the magnetic device.

According to an aspect of the inventive concept, there is provided a method of manufacturing a magnetic device, the method including: sequentially forming a lower magnetic layer, an insulation layer, and an upper magnetic layer on a substrate; forming an upper magnetic layer pattern by patterning the upper magnetic layer until an upper surface of the insulation layer is exposed; and performing an oxidation process on the exposed upper surface of the insulation layer to form an isolation layer pattern from portions of the insulation layer and the lower magnetic layer and to form an insulation layer pattern and a lower magnetic layer pattern from portions of the insulation layer and the lower magnetic layer, where the isolation layer pattern is not formed.

The performing the oxidation process may be performed by a directional plasma oxidation process.

The performing the oxidation process may be performed by applying a biased voltage to the substrate.

The forming of the upper magnetic layer pattern may be performed by an ion etching process using low-mass species.

The forming of the upper magnetic layer pattern may be performed by an ion etching process using low-mass species of H₂, He, Ne, or N₂.

The forming of the upper magnetic layer pattern may be performed by etching the upper magnetic layer using the insulation layer as an etch stop layer.

The lower magnetic layer may have a thickness in a range from about 1 Å to about 40 Å.

The insulation layer may have a thickness in a range from about 1 Å to about 30 Å.

In the operation of forming the upper magnetic layer pattern, etch residues may be formed on sidewalls of the upper magnetic layer, and in the operation of performing the oxidation process, the etch residues may be oxidized to form a sidewall spacer layer on the sidewalls of the upper magnetic layer.

The method may further include removing the sidewall spacer layer by an ion etching process using low-mass species of H₂, He, Ne, or N₂ or a wet etching process.

According to another aspect of the inventive concept, there is provided a method of manufacturing a magnetic device, the method including: sequentially forming a lower magnetic layer, an insulation layer, and an upper magnetic layer; forming an upper magnetic layer pattern on the insulation layer by patterning the upper magnetic layer using the insulation layer as an etch stop layer; forming an isolation layer pattern by transforming portions of the insulation layer and the lower magnetic layer to insulating materials, where the upper magnetic layer pattern is not formed; and forming an insulation layer pattern and a lower magnetic layer pattern from portions of the insulation layer and the lower magnetic layer under the upper magnetic layer pattern.

The forming of the upper magnetic layer pattern may be performed by an ion etching process using low-mass species of H₂, He, Ne, or N₂.

The forming of the isolation layer pattern may include transforming portions of the insulation layer and the lower magnetic layer to insulating materials by performing a directional plasma oxidation process, or a directional plasma nitration process.

The method may further include, forming a sidewall spacer layer on sidewalls of the upper magnetic layer pattern by transforming etch residues formed on the sidewalls of the upper magnetic layer in the operation of forming the upper magnetic layer pattern to insulating materials.

The method may further include removing the sidewall spacer layer by an ion etching process using low-mass species of H₂, He, Ne, or N₂ or a wet etching process.

### BRIEF DESCRIPTION OF THE DRAWINGS

Exemplary embodiments of the inventive concept will be more clearly understood from the following detailed description taken in conjunction with the accompanying drawings in which:

FIG. 1 is a circuit diagram showing a magnetic memory array according to an embodiment of the inventive concept;

FIG. 2 is a cross-sectional view of a magnetic device according to an embodiment of the inventive concept;

FIG. 3 is a cross-sectional view of a magnetic device according to an embodiment of the inventive concept;

FIG. 4 is a cross-sectional view of a magnetic device according to an embodiment of the inventive concept;

FIG. 5 is a cross-sectional view of a magnetic device according to an embodiment of the inventive concept;

FIGS. 6 through 11 are cross-sectional views showing a method of manufacturing a magnetic device according to an embodiment of the inventive concept;

FIG. 12 is a block diagram showing a memory card according to an embodiment of the inventive concept; and

FIG. 13 is a block diagram showing a system according to an embodiment of the inventive concept.

### DETAILED DESCRIPTION OF THE EMBODIMENTS

Hereafter, the inventive concept will be described more fully with reference to the accompanying drawings.

The embodiments of the inventive concept are provided to describe the current inventive concept to those of ordinary skill in the art. This inventive concept may, however, be embodied in many different forms and should not be construed as being limited to the exemplary embodiments set forth herein. Rather, these embodiments are provided so that this disclosure will be thorough and complete, and will fully convey the scope of the invention to those of ordinary skill in the art. In the drawings, lengths and sizes of layers and regions may be exaggerated for convenience of explanation and clarity.

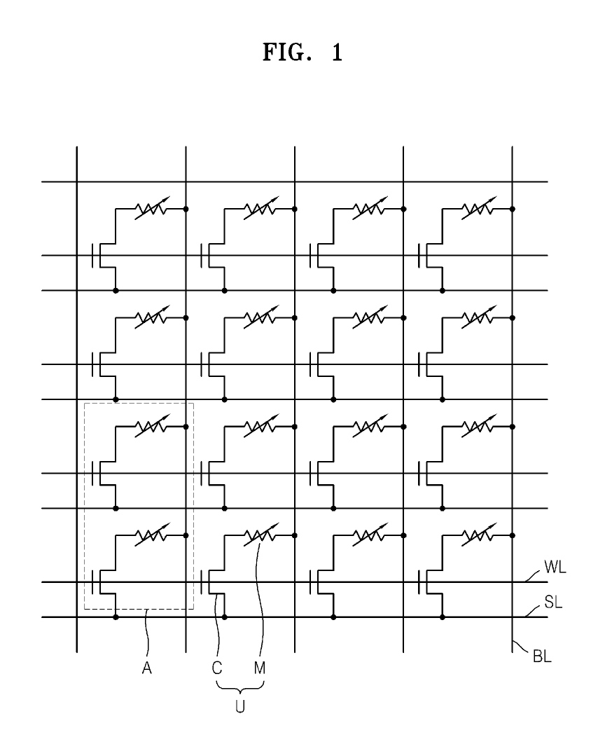

FIG. 1 is a circuit diagram showing a magnetic memory array according to an embodiment of the inventive concept.

Referring to FIG. 1, the magnetic memory array includes unit cells U of a plurality of magnetic memory devices arranged in a matrix type. Each of the unit cells U of the plural magnetic memory devices includes an access region C and a memory region M. The unit cells U of the plural magnetic memory devices are electrically connected to word lines WL and bit lines BL. Also, as depicted in FIG. 1, if the access region C is a transistor, source lines SL that are electrically connected to a source region of the access region C may further be included. The word lines WL and the bit lines BL may be arranged in a predetermined angle, for example, perpendicular to each other. Also, the word lines WL and the bit lines BL may be arranged in a predetermined angle, for example, parallel to each other.

The access region C controls current supply to a memory region M according to a voltage of the word lines WL. The access region C may be a MOS transistor, a bipolar transistor, or a diode.

The memory region M may include a magnetic material and a magnetic tunnel junction (MTJ) device. Also, the memory region M may function as a memory using a spin transfer torque (STT) phenomenon in which the magnetization direction of a magnetic body varies according to an input current.

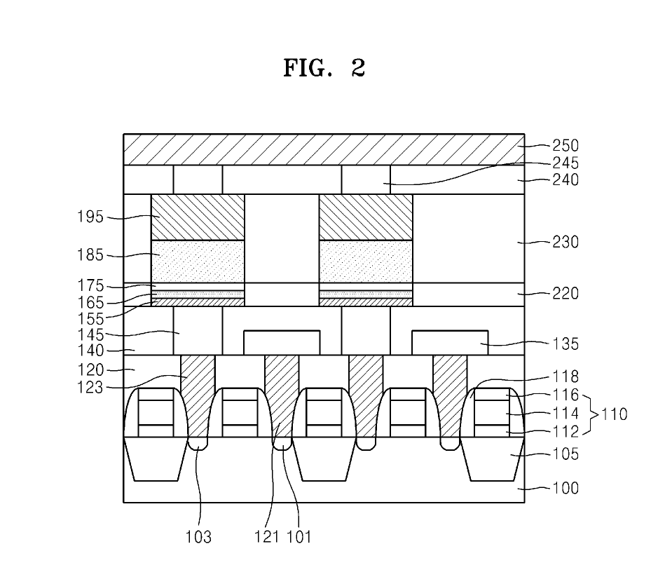

FIG. 2 is a cross-sectional view of a magnetic device such as a magnetic memory device according to an embodiment of the inventive concept. FIG. 2 illustrates the region “A” of the magnetic memory device of FIG. 1.

Referring to FIG. 2, the magnetic memory device includes a substrate 100, a lower contact 145, a lower electrode 155, a lower magnetic layer pattern 165, an insulation layer pattern 175, an upper magnetic layer pattern 185, an upper electrode 195, and an upper contact 245. Meanwhile, a gate structure 110 and first and second impurity regions 101 and 103 may be further formed between the lower contact 145 and the substrate 100 to form a switching device such as transistors that correspond to the access region C of FIG. 1. Instead of the transistors, diodes that are electrically connected to the lower contact 145 may be formed between the lower contact 145 and the substrate 100, and the diodes may correspond to the access region C of FIG. 1. The lower magnetic layer pattern 165, the insulation layer pattern 175, and the upper magnetic layer pattern 185 may function as an MTJ pattern, and the MTJ pattern may correspond to the memory region M of FIG. 1.

In FIG. 2, a vertical magnetization type MTJ device is depicted. In the vertical magnetization type MTJ device, a thin insulation layer pattern is formed between a fixed layer and a free layer, and the magnetization directions of the fixed layer and the free layer are substantially perpendicular to the substrate 100. The magnetization direction of the fixed layer may not vary by a stray field, but the magnetization direction of the free layer may vary by the stray field. Accordingly, when the direction of a current that flows in the vertical magnetization type MTJ device is changed, the magnetization direction of the free layer may vary, and accordingly, the magnetic resistance value of the vertical magnetization type MTJ device is changed. According to the variation of the magnetic resistance, data “0” or “1” may be written.

In the current embodiment, the vertical magnetization type MTJ device in which the lower magnetic layer pattern 165 functions as a free layer and the upper magnetic layer pattern 185 functions as a fixed layer is described as an example. Alternatively, the vertical magnetization type MTJ device in which the lower magnetic layer pattern 165 functions as a fixed layer and the upper magnetic layer pattern 185 functions as a free layer may also be formed.

The substrate 100 may be a semiconductor substrate such as a silicon substrate, a germanium substrate, a silicon-germanium substrate, or a silicon-on-insulator (SOI) substrate. An isolation layer 105 that defines an active region may be formed on the substrate 100. The isolation layer 105 may have a shallow trench isolation (STI) structure.

The gate structure 110 includes a gate insulation layer pattern 112, a gate electrode 114, and a gate mask 116 which are sequentially stacked on the substrate 100. Spacers 118 may further be formed on sidewalls of the gate structure 110.

The first and second impurity regions 101 and 103 may be formed at upper portions of the substrate 100 adjacent to the gate structure 110.

A first insulating interlayer 120 may be formed on the substrate 100. In an example embodiment, the first insulating interlayer 120 may include silicon oxide, silicon nitride, or silicon oxynitride. For example, the silicon oxide may be boro-phospho-silicate glass (BPSG), tonen silazene (TOSZ), undoped silicate glass (USG), spin-on-glass (SOG), flowable oxide (FOX), tetraethylortho silicate (TEOS), or a high density plasma chemical vapor deposition (HDP-CVD) oxide.

A first plug 121 and a second plug 123 may further be formed through the first insulating interlayer 110 to be connected to the first impurity region 101 and the second impurity region 103, respectively. The first plug 121 may be connected to a source line 135 formed on the first insulating interlayer 110. A second insulating interlayer 140 may be formed on the first insulating interlayer 110 to cover the source line 135.

The lower contact 145 that is electrically connected to the second plug 123 may be formed through the second insulating interlayer 140. The lower contact 145 may include metal, metal nitride, or polysilicon. For example, the lower contact 145 may include Ti, TiN, W, WN or polysilicon, or a combination thereof.

The lower electrode 155 may be formed on the lower contact 145 and the second insulating interlayer 140. In an example embodiment, the lower electrode 155 may include a conductive material such as Ti, Ta, Ru, TiN, TaN, W, alone or in combination thereof. For example, the lower electrode 155 may have a double-layered structure of Ru/Ti, Ru/Ta, Ru/TiN, Ru/TaN, or TiN/W. In an example embodiment, the lower electrode 155 may be formed to have a thickness of approximately 30 Å or less.

The lower magnetic layer pattern 165 may be formed on the lower electrode 155. In an example embodiment, the lower magnetic layer pattern 165 may include at least one selected from the group consisting of Fe, Co, Ni, Pd, and Pt. For example, the lower magnetic layer pattern 165 may include a Fe—Pt alloy, a Fe—Pd alloy, a Co—Pd alloy, a Co—Pt alloy, a Fe—Ni—Pt alloy, a Co—Fe—Pt alloy, or a Co—Ni—Pt alloy. In another embodiment, the lower magnetic layer pattern 165 may further include at least one from B, C, Cu, Ag, Au, and Cr. The lower magnetic layer pattern 165 may be formed to have a thickness of approximately 40 Å or less.

The insulation layer pattern 175 is formed on the lower magnetic layer pattern 165. In an example embodiment, the insulation layer pattern 175 may include an oxide selected from the group consisting of B₂O₃, SiO₂, MgO, and Al₂O₃. The insulation layer pattern 175 may be formed to a thickness of approximately 30 Å or less.

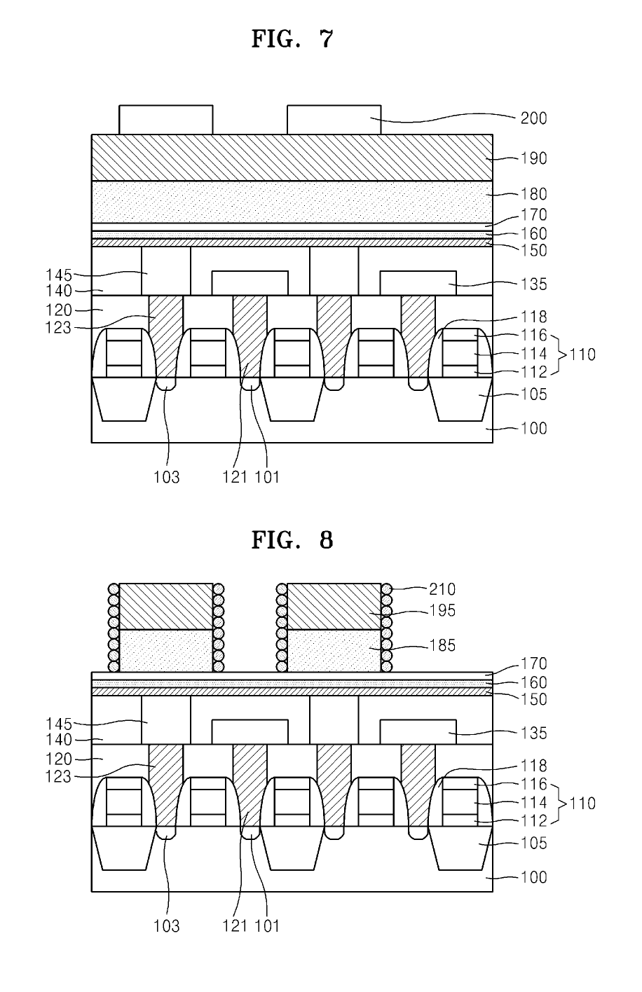

The isolation layer pattern 220 may be formed on sidewalls of the lower electrode 155, the lower magnetic layer pattern 165, and the insulation layer pattern 175 and on the second insulating interlayer 140. That is, the isolation layer pattern 220 may be formed on the second insulating interlayer 140 to surround the sidewalls of the lower electrode 155, the lower magnetic layer pattern 165, and the insulation layer pattern 175. Since the isolation layer pattern 220 may include metal oxide formed by oxidizing a lower electrode layer, a lower magnetic layer and an insulation layer (FIG. 7), the isolation layer pattern 220 may include an insulating material. Also, the lower electrode 155 of the memory device may be electrically isolated from the lower electrode 155 of an adjacent cell by the isolation layer pattern 220. The isolation layer pattern 220 may be formed to have a thickness of approximately 100 Å or less.

The upper magnetic layer pattern 185 may be formed on the insulation layer pattern 175. In an example embodiment, the upper magnetic layer pattern 185 may have a synthetic antiferromagnetic (SAF) structure. In some embodiments, the lower magnetic layer pattern 165 may also have a SAF structure. The SAF structure may be a multi-layered structure in which a plurality of magnetic layers and at least one intermediate layer are sequentially stacked. For example, the SAF structure may be a multi-layered structure in which a first magnetic layer, a first intermediate layer, a second magnetic layer, a second intermediate layer, and a third magnetic layer are sequentially stacked. For example, the first magnetic layer may include a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, an Ni—Fe alloy, a Co—Fe alloy, an Ni—Fe—B alloy, a Co—Fe—B alloy, an Ni—Fe—Si—B alloy, or a Co—Fe—Si—B. The second and third magnetic layers may include a single layer or a multilayer of Co, Fe, Pt, or Pd. The intermediate layer may include Ru, Ta, Cr, or Cu. For example, the SAF structure may have a multi-layered structure of CoFeB/Ta/(Co/Pt)n/Ru/(Co/Pt)m.

The upper electrode 195 may be formed on the upper magnetic layer pattern 185. In an example embodiment, the upper electrode 195 may include a conductive material such as Ti, Ta, Ru, TiN, TaN, or W. These materials may be used alone or in combination thereof. For example, the upper electrode 195 may have a double-layered structure of Ru/Ti, Ru/Ta, Ru/TiN, Ru/TaN, or TiN/W.

A third insulating interlayer 230 may be formed on sidewalls of the upper magnetic layer pattern 185 and the upper electrode 195 and on the isolation layer pattern 220. That is, the third insulating interlayer 230 may be formed on the isolation layer pattern 220 to surround the upper magnetic layer pattern 185 and the upper electrode 195. In an example embodiment, the third insulating interlayer 230 may include silicon oxide, silicon nitride, or silicon oxynitride.

A fourth insulating interlayer 240 may be formed on the upper electrode 195 and the third insulating interlayer 230. The fourth insulating interlayer 240 may include silicon oxide, silicon nitride, or silicon oxynitride.

The upper contact 245 through the fourth insulating interlayer 240 may be formed on the upper electrode 195.

A bit line 250 may be formed on the upper contact 245. The bit line 250 may extend in a first direction which is substantially parallel to a top surface of the substrate 100.

In the magnetic device, the isolation layer pattern 220 that may be formed by oxidizing a lower electrode layer, a lower magnetic layer, and an insulation layer may electrically isolate a cell from adjacent cells. Therefore, even though the dimension of a unit cell is reduced, a patterning process may be easily performed. Accordingly, the scale down of the magnetic device is possible, thereby increasing integration density of the magnetic device.

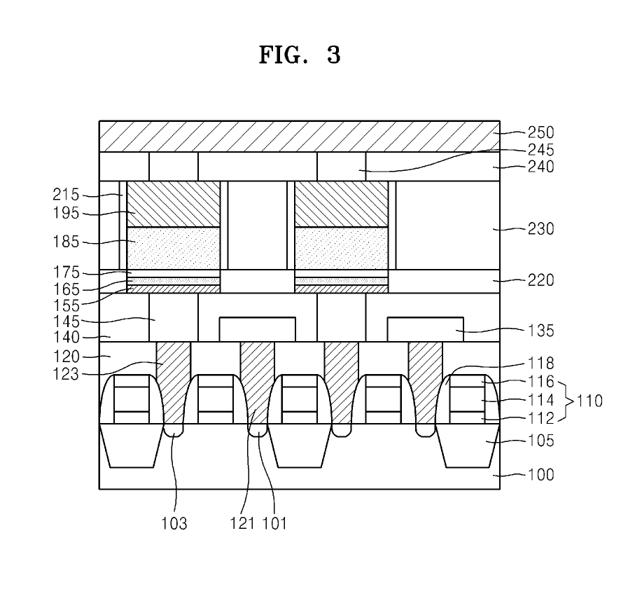

FIG. 3 is a cross-sectional view of a magnetic device according to an embodiment of the inventive concept.

Referring to FIG. 3, the magnetic device includes a substrate 100, a lower contact 145, a lower electrode 155, a lower magnetic layer pattern 165, an insulation layer pattern 175, an upper magnetic layer pattern 185, an upper electrode 195, a sidewall spacer layer 215, and an upper contact 245. A switching device such as a transistor or a diode that is electrically connected to the lower contact 145 may further be formed between the lower contact 145 and the substrate 100.

In the current embodiment, the vertical magnetization type MTJ device in which the lower magnetic layer pattern 165 is a free layer and the upper magnetic layer pattern 185 is a fixed layer is described as an example. However, unlike this, the vertical magnetization type MTJ device in which the lower magnetic layer pattern 165 is the fixed layer and the upper magnetic layer pattern 185 is the free layer may also be formed.

The lower contact 145 that penetrates through the second insulating interlayer 140 may be formed on the substrate 100, and the lower electrode 155, the lower magnetic layer pattern 165, and the insulation layer pattern 175 are sequentially stacked on the lower contact 145 and the second insulating interlayer 140. An isolation layer pattern 220 may be formed on the second insulating interlayer 140 to surround the lower electrode 155, the lower magnetic layer pattern 165, and the insulation layer pattern 175. The isolation layer pattern 220 may include a metal oxide formed by oxidizing a lower electrode layer, a lower magnetic layer, and an insulation layer.

The upper magnetic layer pattern 185 and the upper electrode 195 are sequentially stacked on the insulation layer pattern 175.

A sidewall spacer layer 215 may be formed on sidewalls of the upper magnetic layer pattern 185 and the upper electrode 195. In an example embodiment, the sidewall spacer layer 215 may include a metal oxide formed by oxidizing metals included in the upper magnetic layer pattern 185 and the upper electrode 195.

A third insulating interlayer 230 may be formed on sidewalls of the sidewall spacer layer 215 and the isolation layer pattern 220, and a fourth insulating interlayer 240 may be formed on the third insulating interlayer 230 and the upper electrode 195. The upper contact 245 that penetrates through the fourth insulating interlayer 240 may be formed on the upper electrode 195. A bit line 250 may be formed on the upper contact 245 and the fourth insulating interlayer 240.

In the magnetic device, the isolation layer pattern 220 that is formed by oxidizing a lower electrode layer, a lower magnetic layer, and an insulation layer may electrically isolate a cell from adjacent cells, and thus, even though the dimension of the cell is reduced, a patterning process may be readily performed. Also, the oxidation of the upper magnetic layer pattern 185 may be prevented by the sidewall spacer layer 215 formed on sidewalls of the upper electrode 195 and the upper magnetic layer pattern 185. Accordingly, the scale down of the magnetic device is possible, thereby increasing the integration density.

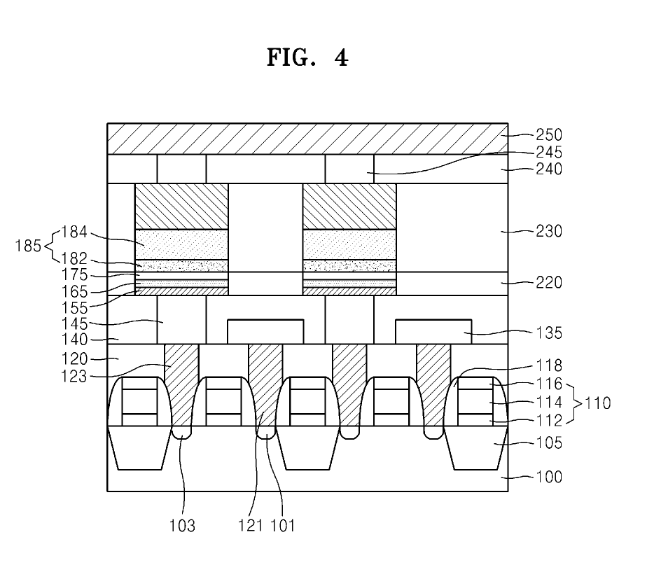

FIG. 4 is a cross-sectional view of a magnetic device according to an embodiment of the inventive concept.

Referring to FIG. 4, the magnetic device includes a substrate 100, a lower contact 145, a lower electrode 155, a lower magnetic layer pattern 165, an insulation layer pattern 175, an upper magnetic layer pattern 185, an upper electrode 195, and an upper contact 245. A transistor or a diode that is electrically connected to the lower contact 145 may further be formed between the lower contact 145 and the substrate 100.

In the current embodiment, the vertical magnetization type MTJ device in which the lower magnetic layer pattern 165 is a free layer and the upper magnetic layer pattern 185 is a fixed layer is described as an example. However, unlike this, the vertical magnetization type MTJ device in which the lower magnetic layer pattern 165 is the fixed layer and the upper magnetic layer pattern 185 is the free layer may also be formed.

The lower contact 145 through a second insulating interlayer 140 may be formed on the substrate 100.

The lower electrode 155 may be formed on the lower contact 145 and the second insulating interlayer 140. In an example embodiment, the lower electrode 155 may include a single layer or a multiple layer of a conductive material selected from the group consisting of Ti, Ta, Ru, TiN, TaN, and W. In an example embodiment, the lower electrode 155 may be formed to have a thickness of approximately 30 Å or less.

The lower magnetic layer pattern 165 may be formed on the lower electrode 155. In an example embodiment, the lower magnetic layer pattern 165 may include at least one selected from the group consisting of Fe, Co, Ni, Pd, and Pt. For example, the lower magnetic layer pattern 165 may include a Fe—Pt alloy, a Fe—Pd alloy, a Co—Pd alloy, a Co—Pt alloy, a Fe—Ni—Pt alloy, a Co—Fe—Pt alloy, or a Co—Ni—Pt alloy. In another embodiment, the lower magnetic layer pattern 165 may further include at least one material selected from the group consisting of B, C, Cu, Ag, Au, and Cr. The lower magnetic layer pattern 165 may be formed to have a thickness of approximately 40 Å or less.

The insulation layer pattern 175 may be formed on the lower magnetic layer pattern 165. In an example embodiment, the insulation layer pattern 175 may include B₂O₃, SiO₂, MgO, or Al₂O₃. The insulation layer pattern 175 may be formed to have a thickness of approximately 30 Å or less.

The isolation layer pattern 220 may be formed on sidewalls of the lower electrode 155, the lower magnetic layer pattern 165, and the insulation layer pattern 175 and on the second insulating interlayer 140. Since the isolation layer pattern 220 includes metal oxide formed by oxidizing a lower electrode layer, a lower magnetic layer and an insulation layer, the isolation layer pattern 220 may include an insulating material. Also, the lower electrode 155 of the memory device may be electrically isolated from the lower electrode 155 of an adjacent cell. The isolation layer pattern 220 may be formed to have a thickness of approximately 100 Å or less.

The upper magnetic layer pattern 185 may include a pinning layer 182 and a pinned layer 184 which are sequentially stacked on the insulation layer pattern 175.

The pinning layer 182 may include an antiferromagnetic material, and the magnetization direction is fixed in a direction substantially parallel to the substrate 100. In an example embodiment, the pinning layer 182 may include a Pt—Mn alloy, an Ir—Mn alloy, an Ni—Mn alloy, or a Fe—Mn alloy.

The magnetization direction of the pinned layer 184 may be fixed by the pinning layer 182. In an example embodiment, the pinned layer 184 may include a ferromagnetic material, such as Co, Fe, Pt, or Pd, and the pinned layer 184 may have an SAF structure. The SAF structure may be a multi-layered structure in which a plurality of magnetic layers and at least one intermediate layer are sequentially stacked. For example, the SAF structure may be a multi-layered structure in which a first magnetic layer, an intermediate layer, and a second magnetic layer are sequentially stacked. Also, the SAF structure may be a multi-layered structure in which a first magnetic layer, a first intermediate layer, a second magnetic layer, a second intermediate layer, and a third magnetic layer are sequentially stacked. For example, the first magnetic layer may include a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, an Ni—Fe alloy, a Co—Fe alloy, an Ni—Fe—B alloy, a Co—Fe—B alloy, an Ni—Fe—Si—B alloy, or a Co—Fe—Si—B. The second and third magnetic layers may include a single layer or a multilayer of Co, Fe, Pt, or Pd. The intermediate layer may include Ru, Ta, Cr, or Cu.

The upper electrode 195 may be formed on the upper magnetic layer pattern 185. In an example embodiment, the upper electrode 195 may include a single layer or a multilayer of a conductive material selected from the group consisting of Ti, Ta, Ru, TiN, TaN, and W.

A third insulating interlayer 230 may be formed on sidewalls of the upper magnetic layer pattern 185 and the upper electrode 195 and on the isolation layer pattern 220. A fourth insulating interlayer 240 may be formed on the upper electrode 195 and the third insulating interlayer 230. The third and fourth insulating interlayers 230 and 240 may include silicon oxide, silicon nitride, or silicon oxynitride.

The upper contact 245 through the fourth insulating interlayer 240 may be formed on the upper electrode 195, and a bit line 250 may be formed on the upper contact 245.

In the magnetic device, the isolation layer pattern 220 that is formed by oxidizing a lower electrode layer, a lower magnetic layer, and an insulation layer may electrically isolate a cell from adjacent cells. Therefore, even though the dimension of a unit cell is reduced, a patterning process may be easily performed. Accordingly, the scale down of the magnetic device is possible, thereby increasing integration density of the magnetic device.

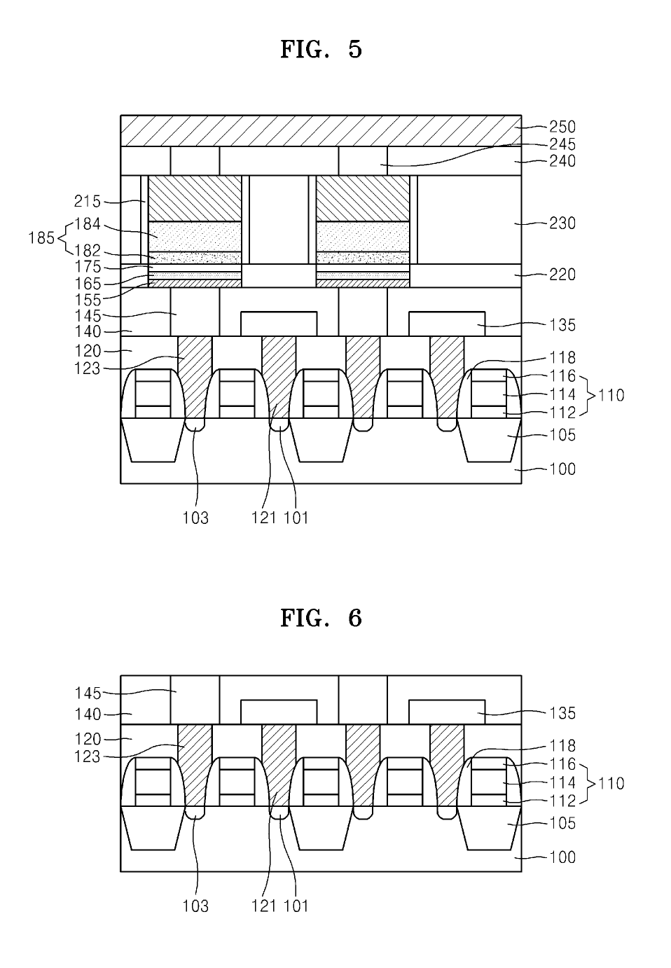

FIG. 5 is a cross-sectional view of a magnetic device according to an embodiment of the inventive concept.

Referring to FIG. 5, the magnetic device includes a substrate 100, a lower contact 145, a lower electrode 155, a lower magnetic layer pattern 165, an insulation layer pattern 175, an upper magnetic layer pattern 185, an upper electrode 195, a sidewall spacer layer 215, and an upper contact 245.

In the current embodiment, a vertical magnetization type MTJ device in which the lower magnetic layer pattern 165 is a free layer and the upper magnetic layer pattern 185 is a fixed layer is described as an example. However, unlike this, the vertical magnetization type MTJ device in which the lower magnetic layer pattern 165 is the fixed layer and the upper magnetic layer pattern 185 is the free layer may also be formed.

The lower contact 145 that penetrates through a second insulating interlayer 140 may be formed on the substrate 100, and the lower electrode 155, the lower magnetic layer pattern 165, and the insulation layer pattern 175 may be sequentially stacked on the lower contact 145 and the second insulating interlayer 140. An isolation layer pattern 220 that surrounds the lower electrode 155, the lower magnetic layer pattern 165, and the insulation layer pattern 175 may be formed on the second insulating interlayer 140. The isolation layer pattern 220 may include metal oxide formed by oxidizing a lower electrode layer, a lower magnetic layer, and an insulation layer.

The upper magnetic layer pattern 185 may include a pinning layer 182 and a pinned layer 184 which are sequentially stacked on the insulation layer pattern 175. The upper electrode 195 may be formed on the upper magnetic layer pattern 185.

A sidewall spacer layer 215 may be formed on sidewalls of the upper magnetic layer pattern 185 and the upper electrode 195. In an example embodiment, the sidewall spacer layer 215 may include a metal oxide formed by oxidizing metals included in the upper magnetic layer pattern 185 and the upper electrode 195.

A third insulating interlayer 230 may be formed on sidewalls of the sidewall spacer layer 215 and the isolation layer pattern 220, and a fourth insulating interlayer 240 may be formed on the third insulating interlayer 230 and the upper electrode 195. The upper contact 245 that penetrates through the fourth insulating interlayer 240 may be formed on the upper electrode 195. A bit line 250 may be formed on the upper contact 245 and the fourth insulating interlayer 240.

In the magnetic device, the isolation layer pattern 220 that is formed by oxidizing a lower electrode layer, a lower magnetic layer, and an insulation layer may electrically isolate a cell from adjacent cells, and thus, even though the dimension of the cell is reduced, a patterning process may be readily performed. Also, the oxidation of the upper magnetic layer pattern 185 may be prevented by the sidewall spacer layer 215 formed on sidewalls of the upper electrode 195 and the upper magnetic layer pattern 185. Accordingly, the scale down of the magnetic device is possible, thereby increasing the integration density. FIGS. 6 through 11 are cross-sectional views showing a method of manufacturing a magnetic device according to an embodiment of the inventive concept. In the current embodiment, a method of manufacturing a magnetic device that includes a vertical magnetization type MTJ pattern is described as an example. However, unlike this, the magnetic device may include a horizontal magnetization type MTJ pattern. In other words, the magnetic orientation of the various magnetic layers can be either in plane or perpendicular. In some embodiments, the magnetic orientation of the various magnetic layers can be combinations of in-plane and perpendicular magnetic orientation.

Referring to FIG. 6, an isolation layer 105 may be formed on a substrate 100. In an example embodiment, the isolation layer 105 may be formed by a shallow trench isolation (STI) process.

A gate insulation layer, a gate electrode layer, and a gate mask layer may be sequentially formed on the substrate 100, and patterned by, for example, using a photolithography process to form a plurality of gate structures 110, each includes a gate insulation layer pattern 112, a gate electrode 114, and a gate mask 116 which are sequentially stacked on the substrate 100. The gate insulation layer may be formed of silicon oxide or metal oxide. In some other embodiments, the gate insulation layer may include a high-k dielectric material such as a hafnium oxide or hafnium silicate. The gate electrode layer may be formed of doped polysilicon or metal. The gate mask layer may be formed of silicon nitride.

Then, first and second impurity regions 101 and 103 may be formed at upper portions of the substrate 100 adjacent to the gate structures 110 by an ion implantation process using the gate structures 110 as ion implantation masks. The first and second impurity regions 101 and 103 may function as source/drain regions of a transistor.

The gate structures 110 and the first and second impurity regions 101 and 103 may form a transistor. Meanwhile, spacers 118 may be formed on sidewalls of the gate structures 110 using, for example, silicon nitride.

A first insulating interlayer 120 that covers the gate structures 110 and the spacers 118 is formed on the substrate 100. First holes (not shown) that expose the first and second impurity regions 101 and 103 are formed by partly removing the first insulating interlayer 120. In an example embodiment, the first holes may be self-aligned with the spacers 118 formed on the gate structures 110.

A first conductive layer that fills the first holes may be formed on the first insulating interlayer 120. An upper portion of the first conductive layer may be removed by a mechanical chemical polishing (CMP) process and/or an etch-back process until the first insulating interlayer 120 is exposed so that first and second plugs 121 and 123 may be formed in the first holes. The first plug 121 may contact the first impurity region 101, and the second plug 123 may contact the second impurity region 103. The first conductive layer may be formed of a conductive material such as doped polysilicon or metal. The first plug 121 may function as a source line contact.

A second conductive layer (not shown) may be formed on the first insulating interlayer 120 to contact the first plug 121, and then patterned to form a source line 135. The second conductive layer may be formed of a conductive material such as doped polysilicon or a metal. Next, a second insulating interlayer 140 that covers the source line 135 may be formed on the first insulating interlayer 120. Second holes (not shown) that expose the second plug 123 are formed by partly removing the second insulating interlayer 140, and afterwards, a third conductive layer that fills the second holes may be formed on the second plug 123 and the second insulating interlayer 140. Thus, an upper part of the third conductive layer may be removed by a CMP process or an etch-back process until the second insulating interlayer 140 is exposed so that the lower contacts 145 may be formed in the second holes. The third conductive layer may be formed of a material selected from the group consisting of Ti, Ta, TiN, TaN, W, and doped polysilicon.

Referring to FIG. 7, a lower electrode layer 150 may be formed on the second insulating interlayer 140 and the lower contacts 145.

The lower electrode layer 150 may be formed of a conductive material, such as Ti, Ta, Ru, TiN, TaN, or W by an atomic layer deposition (ALD) process or a chemical vapor deposition (CVD) process. For example, the lower electrode layer 150 may have a double-layered structure of Ru/Ti, Ru/Ta, Ru/TiN, Ru/TaN, or TiN/W. In an example embodiment, the lower electrode layer 150 may be formed to have a thickness of approximately 30 Å or less.

A lower magnetic layer 160 may be formed on the lower electrode layer 150. In an example embodiment, the lower magnetic layer 160 may be formed by an ALD process or a CVD process using a Fe—Pt alloy, a Fe—Pd alloy, a Co—Pd alloy, a Co—Pt alloy, a Fe—Ni—Pt alloy, a Co—Fe—Pt alloy, or a Co—Ni—Pt alloy. In another embodiment, the lower magnetic layer 160 may further include at least one selected from the group consisting of B, C, Cu, Ag, Au, and Cr. The lower magnetic layer 160 may be formed to have a thickness of approximately 40 Å or less.

An insulation layer pattern 170 may be formed on the lower magnetic layer 160. In an example embodiment, the insulation layer pattern 170 may be formed using B₂O₃, SiO₂, MgO, or Al₂O₃ by an ALD process or a CVD process. The insulation layer pattern 170 may be formed to have a thickness of approximately 30 Å or less.

An upper magnetic layer 180 may be formed on the insulation layer pattern 170. The upper magnetic layer 180 may be formed to have a multi-layered structure in which a plurality of magnetic layers and at least one intermediate layer are sequentially stacked. In an example embodiment, the upper magnetic layer 180 may be formed to have a multi-layered structure in which a first magnetic layer, a first intermediate layer, a second magnetic layer, a second intermediate layer, and a third magnetic layer are sequentially stacked. The first magnetic layer may be formed of a material selected from the group consisting of a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, an Ni—Fe alloy, a Co—Fe alloy, an Ni—Fe—B alloy, a Co—Fe—B alloy, an Ni—Fe—Si—B alloy, and a Co—Fe—Si—B. The second and third magnetic layers may include a single layer or a multilayer of Co, Fe, Pt, or Pd. The intermediate layer may include Ru, Ta, Cr, or Cu. For example, the upper magnetic layer 180 may have a multi-layered structure of CoFeB/Ta/(Co/Pt)n/Ru/(Co/Pt)m. The upper magnetic layer 180 may be formed by a CVD process or an ALD process.

An upper electrode layer 190 may be formed on the upper magnetic layer 180. In an example embodiment, the upper electrode layer 190 may be formed by an ALD process or a CVD process using a conductive material selected from the group consisting of Ti, Ta, Ru, TiN, TaN, and W. For example, the upper electrode layer 190 may have a double-layered structure of Ru/Ti, Ru/Ta, Ru/TiN, Ru/TaN, or TiN/W.

A mask pattern 200 may be formed on the upper electrode layer 190. In an example embodiment, the mask pattern 200 may be a photoresist pattern or a hard mask pattern that includes silicon oxide or silicon nitride.

Referring to FIG. 8, an upper electrode 195 may be formed by patterning the upper electrode layer 190 using the mask pattern 200 as an etch mask.

Then, an upper magnetic layer pattern 185 may be formed by patterning the upper magnetic layer 180 using the mask pattern 200 and the upper electrode 195 as etch masks until an upper surface of the insulation layer 170 is exposed. In an example embodiment, the upper magnetic layer 180 may be patterned by an ion etching process such as a reactive ion etching (RIE) using low-mass species. The etching process using low-mass species may be performed using at least one selected from the group consisting of H₂, He, N₂, or Ne. Since the ion etching process uses gases having a relatively small molecular weight, the insulation layer 170 may function as an etch stop layer.

In the above RIE process, etch residues 210 of the upper magnetic layer 180 may be re-deposited on sidewalls of the patterned upper magnetic layer pattern 185 and the upper electrode 195. When an upper magnetic layer, an insulation layer, and a lower magnetic layer are patterned in the same processing step using a conventional patterning method, etch residues may be re-deposited on the patterned upper magnetic layer, the insulation layer, and the lower magnetic layer. In this case, the upper magnetic layer and the lower magnetic layer may be electrically connected to each other by the etch residues, and thus, a device failure may occur in the memory device due to an electrical bridging. According to the current embodiment, the upper magnetic layer 180 may be patterned using the insulation layer 170 as an etch stop layer. Therefore, a failure due to electrical bridging may be avoided.

Next, the mask pattern 200 may be removed.

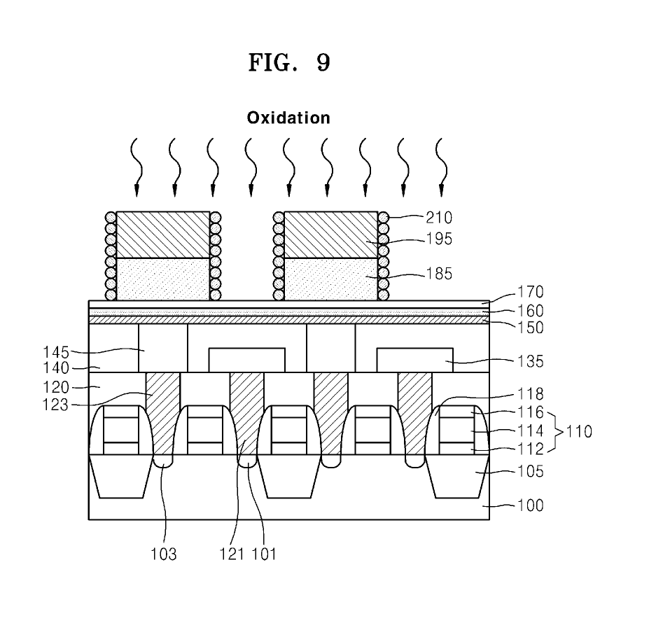

Referring to FIG. 9, portions of the insulation layer 170 (exposed by the above patterning step), portions of the lower magnetic layer 160, and the lower electrode layer 150 disposed under the exposed portions of the insulating layer 170, and the etch residues 210 may be oxidized by performing an oxidation process on the substrate 100. In an example embodiment, the oxidation process may be a directional plasma oxidation process that uses oxygen (O₂) gas or ozone (O₃) gas. The oxidation process may be a directional plasma oxidation in which a biased voltage is applied to the substrate 100. Alternatively, the oxidation process may be a thermal oxidation process in which an annealing is performed under an oxygen atmosphere.

Portions of the insulation layer 170, the lower magnetic layer 160, the lower electrode layer 150 that are not covered by the upper electrode 195 and the upper magnetic layer pattern 185 may be oxidized in the oxidation process, and turned into insulating materials. Also, the etch residues 210 which are redeposited on the sidewalls of the upper electrode 195 and the upper magnetic layer pattern 185 may also be oxidized in the oxidation process, and turned into insulating materials.

In the current embodiment, a method of transforming or turning the insulation layer 170, the upper magnetic layer 180, the lower electrode layer 150, and the etch residues 210 into insulating materials by an oxidation process is described. In some other embodiments, the exposed portions may be turned into insulating materials by performing other suitable processes such as a nitridation process. The nitridation process may include a directional plasma nitridation process.

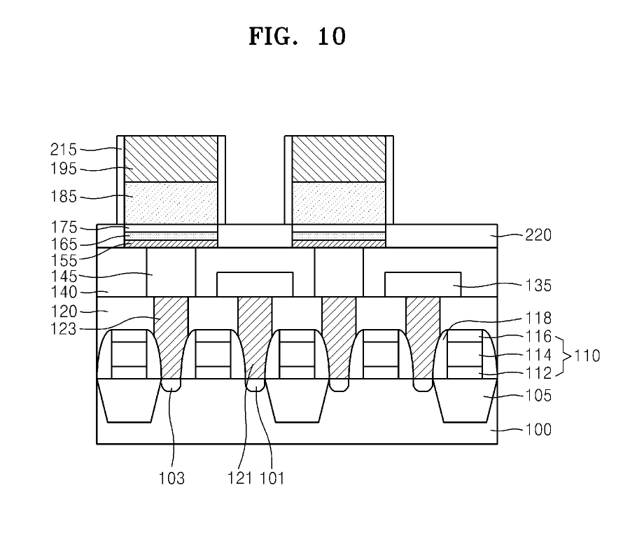

Referring to FIG. 10, portions of the insulation layer 170, the lower magnetic layer 160, and the lower electrode layer 150 that are not covered by the upper electrode 195 and the upper magnetic layer pattern 185 may therefore form the isolation layer pattern 220. Consequently, from other portions of the insulation layer 170, the lower magnetic layer 160, and the lower electrode layer 150 that are covered by the upper electrode 195 and the upper magnetic layer pattern 185, the insulation layer pattern 175, the lower magnetic layer pattern 165, and the lower electrode 155 may be formed. In other words, the isolation layer pattern 220 may be formed from a region of the insulation layer 170 and the lower magnetic layer 160, thereby forming the insulation layer pattern 175 and the lower magnetic layer pattern 165 in another region of the insulation layer 170 and the lower magnetic layer 160 under the upper magnetic layer pattern 185.

Since an upper part of the isolation layer pattern 220 is formed by performing an oxidation process on the insulation layer 170 that mainly includes oxide, the upper part of the isolation layer pattern 220 is not substantially changed by the oxidation process. However, a lower part of the isolation layer pattern 220 may be formed by performing an oxidation process on the lower magnetic layer 160 and the lower electrode layer 150. Since the lower magnetic layer 160 and the lower electrode layer 150 include metal of Co, Pt, and Pd, the lower part of the isolation layer pattern 220 includes a metal oxide formed by oxidizing the above metal. The metal oxide may be electrically insulative. According to the current embodiment, since the lower magnetic layer 160 and the lower electrode layer 150 are formed relatively thin to a thickness of approximately 70 Å or less, the lower magnetic layer 160 and the lower electrode layer 150 may be sufficiently oxidized during the oxidation process.

In an example embodiment, the oxidation process may be performed while a biased voltage is applied to the substrate 100. In this case, the oxidation speed may increase in a direction of the biased voltage is applied. For example, the oxidation speed in a second direction which is perpendicular to the upper surface of the substrate 100 may be increased substantially more than the speed of oxidation in a first direction parallel to the upper surface of the substrate 100. Thus, the lower magnetic layer 160 and the lower electrode layer 150 may be sufficiently oxidized in the second direction. Therefore, the oxidation of the sidewall portion of the lower magnetic layer pattern 165 may be substantially reduced.

Accordingly, the lower electrode 155 and the lower magnetic layer pattern 165 may be electrically isolated from the lower electrode 155 and the lower magnetic layer pattern 165 of an adjacent cell by the isolation layer pattern 220 that includes insulating materials. Also, the process of patterning of the lower electrode 155 and the lower magnetic layer pattern 165 and the deposition process of the isolation layer may be omitted, and thus, the manufacturing process may be easy.

A sidewall spacer layer 215 may be formed on sidewalls of the upper electrode 195 and the upper magnetic layer pattern 185. The sidewall spacer layer 215 may include a metal oxide formed from the etch residues 210 during the oxidation process. Sidewalls of the upper magnetic layer pattern 185 may not be exposed to the oxidation atmosphere because of the etch residues 210 re-deposited on the sidewalls of the upper magnetic layer pattern 185, and thus, the oxidation of the upper magnetic layer pattern 185 may be substantially reduced. Also, the etch residues 210 re-deposited on the sidewalls of the upper magnetic layer pattern 185 may be oxidized in the oxidation process, and thus, form the sidewall spacer layer 215. Therefore, the oxidation of the upper magnetic layer pattern 185 may be substantially reduced. Accordingly, the degradation of electrical characteristics of the upper magnetic layer pattern 185 due to the oxidation of the sidewalls of the upper magnetic layer pattern 185 may be prevented.

Portions of the sidewalls of the upper magnetic layer pattern 185 turned into an oxide may have a thickness similar to that of the isolation layer pattern 220. Therefore, if the upper magnetic layer pattern 185 has a width sufficiently greater than that of the isolation layer pattern 220, even if a portion of the sidewalls of the upper magnetic layer pattern 185 is oxidized, the oxidation of the sidewalls of the upper magnetic layer pattern 185 may not greatly affect the electrical characteristics of the magnetic device. Also, when the oxidation process is performed while applying a biased voltage to the substrate 100, the oxidation speed may be increased in a direction perpendicular to the upper surface of the substrate 100. Therefore, the thickness of the oxidized sidewall portions of the upper magnetic layer pattern 185 may be substantially reduced. Accordingly, even though a portion of the sidewalls of the upper magnetic layer pattern 185 is oxidized, the oxidation may not greatly affect the electrical characteristics of the magnetic device.

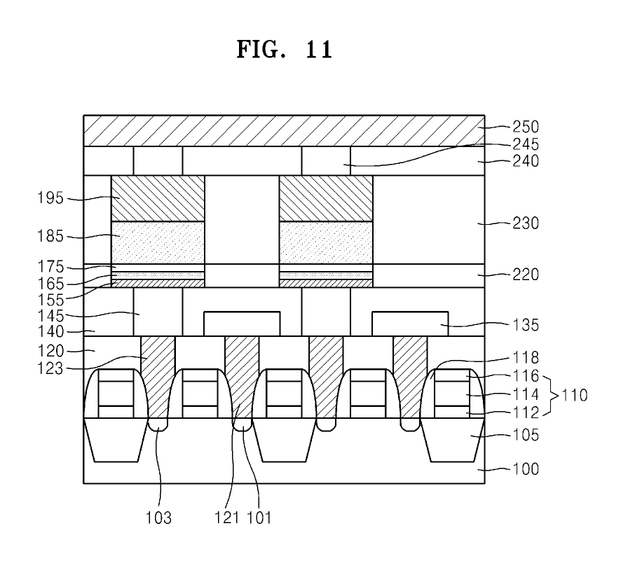

Referring to FIG. 11, the sidewall spacer layer 215 may be removed. In an example embodiment, the sidewall spacer layer 215 formed on the sidewalls of the upper magnetic layer pattern 185 and the upper electrode 195 may be selectively removed by, for example, a tilited ion-etching process using low-mass species. In particular, the tilted ion-etching process using low-mass species such as H₂, He, Ne, or N₂. The insulation layer in the upper region of the isolation layer pattern 220 is not etched by an etch process that uses an etch gas having a small molecular weight, such as H₂, He, Ne, and N₂. Therefore, the isolation layer pattern 220 may function as an etch stop layer. Accordingly, the sidewall spacer layer 215 formed on the sidewalls of the upper magnetic layer pattern 185 and the upper electrode 195 may be selectively removed. Also, when a wet etching process is used, the sidewall spacer layer 215 may be selectively removed using an etchant by which the insulation layer formed on the isolation layer pattern 220 is not etched.

In the current embodiment, the sidewall spacer layer 215 is removed. However, unlike this, the sidewall spacer layer 215 may not be removed.

Next, after forming an insulation layer (not shown) that covers the upper magnetic layer pattern 185 and the upper electrode 195 on the isolation layer pattern 220, a third insulating interlayer 230 may be formed by planarizing the insulation layer until the upper surface of the upper electrode 195 is exposed using a process such as chemical mechanical polishing.

A fourth insulating interlayer 240 may be formed on the third insulating interlayer 230. Afterwards, an opening (not shown) that exposes the upper surface of the upper electrode 195 is formed, and a conductive layer (not shown) that fills the opening is formed. An upper contact 245 electrically connected to the upper electrode 195 may be formed by planarizing the conductive layer until an upper surface of the fourth insulating interlayer 240 is exposed.

A bit line 250 may be formed on the upper contact 245.

The magnetic device is manufactured by performing the processes described above.

In the method of manufacturing a magnetic device, the upper electrode 195 and the upper magnetic layer pattern 185 may be patterned using the insulation layer 170 as an etch stop layer. Therefore, an electrical bridging of the magnetic device may be substantially prevented. Also, the isolation layer pattern 220 that is formed by transforming the insulation layer 170 and the lower magnetic layer 160 to insulating materials by an oxidation process may electrically isolate a cell from adjacent cells. Accordingly, an electrode patterning process may be easy and integration density may be increased.

The principles of the present disclosure may be applied to a variety of other magnetic element or magnetic multilayer structures. A single MTJ or dual MTJ are, therefore, only some examples of such structures. For example, the principles of the present disclosure may be applied to spin logic devices or embedded memories. The spin logic devices may be, for example, all-spin logic (ASL) device and non-volatile spin logic device, the example of which may be seen in U.S. Provisional Application No. 61/512,163, the entire contents of which are incorporated herein by reference.

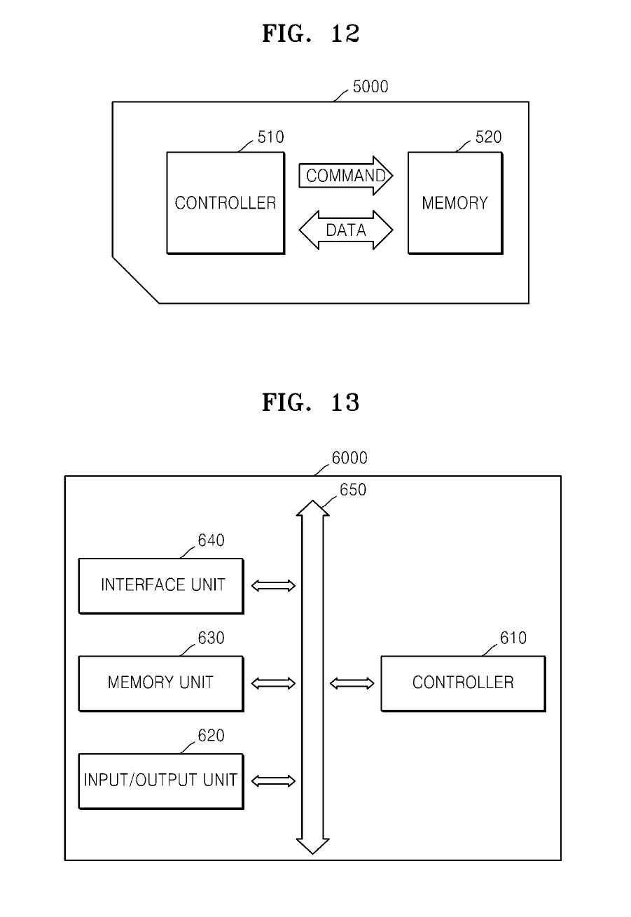

FIG. 12 is a block diagram showing a memory card 5000 according to an embodiment of the inventive concept.

Referring to FIG. 12, a controller 510 and a memory 520 may be arranged in the memory card 5000 to exchange electric signals. For example, when the controller 510 issues a command, the memory 520 may transmit data. The memory 520 may include a magnetic device according to any one of the above-descried exemplary embodiments. A magnetic device according to various exemplary embodiments of the present inventive concept may be arranged in an architecture memory array (not shown) having a variety of shapes corresponding to a corresponding logic gate design that is well known to a technical field to which the present inventive concept pertains to. A memory array in which a plurality of rows and columns are arranged may form one or more memory array bank (not shown). The memory 520 may include a memory array (not shown) or a memory array bank (not shown). Also, the memory card 5000 may further include a typical row decoder (not shown), a column decoder (not shown), I/O buffers (not shown), and/or a control register (not shown) to drive the above-described memory array bank (not shown). The memory card 5000 may be used for a variety of memory cards such as memory stick cards, smart media (SM) cards, secure digital (SD) cards, or multimedia cards (MMC).

FIG. 13 is a block diagram showing a system 6000 according to an embodiment of the inventive concept.

Referring to FIG. 13, the system 6000 may include a controller 610, an input/output (I/O) unit 620, a memory unit 630, and an interface unit 640. The system 6000 may be a mobile system or a system for transmitting or receiving information. The mobile system may be a PDA, a portable computer, a web tablet, a wireless phone, a mobile phone, a smart phone, a digital music player, or a memory card. The controller 610 may execute a program and control the system 6000. The controller 610 may be, for example, a microprocessor, a digital signal processor, a microcontroller, or a device similar thereto. The I/O unit 620 may be used to input or output data of the system 6000. The system 6000 may exchange data with an external apparatus such as a personal computer or a network by being connected to the external apparatus using the I/O unit 620. The I/O unit 620 may be, for example, a keypad, a keyboard, or a display. The memory 630 may store codes and/or data for the operation of the controller 610 and/or store data processed by the controller 610. The memory 630 may include a magnetic memory device according to any one of the above-described exemplary embodiments. The interface unit 640 may be a data transmission path between the system 6000 and an external apparatus. The controller 610, the I/O unit 620, the memory unit 630, and the interface unit 640 may communicate with one another through a bus 650. For example, the system 6000 may be used for mobile phones, MP3 players, navigations, portable multimedia players (PMPs), solid state disks (SSDs), or household appliances.

Throughout the specification, features shown in one embodiment may be incorporated in other embodiments within the spirit and scope of the inventive concept.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used herein, the term magnetic could include ferromagnetic, ferromagnetic or the like. Thus, the term “magnetic” or “ferromagnetic” includes, for example, ferromagnets and ferrimagnets. Further, as used herein, “in-plane” is substantially within or parallel to the plane of one or more of the layers of a magnetic junction. Conversely, “perpendicular” corresponds to a direction that is substantially perpendicular to one or more of the layers of the magnetic junction.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Various operations may be described as multiple discrete steps performed in a manner that is most helpful in understanding the invention. However, the order in which the steps are described does not imply that the operations are order-dependent or that the order that steps are performed must be the order in which the steps are presented.

While the inventive concept has been particularly shown and described with reference to exemplary embodiments thereof, it will be understood that various changes in form and details may be made therein without departing from the spirit and scope of the following claims.

What is claimed is:

1. A method of manufacturing a magnetic device, the method comprising:
sequentially forming a lower magnetic layer, an insulation layer, and an upper magnetic layer on a substrate;
forming an upper magnetic layer pattern by patterning the upper magnetic layer until an upper surface of the insulation layer is exposed; and
performing an oxidation process on the exposed upper surface of the insulation layer to form an isolation layer pattern from portions of the insulation layer and the lower magnetic layer and to form an insulation layer pattern and a lower magnetic layer pattern from portions of the insulation layer and the lower magnetic layer, where the isolation layer pattern is not formed.

2. The method of claim 1, wherein the performing the oxidation process is performed by a directional plasma oxidation process.

3. The method of claim 2, wherein the performing the oxidation process is performed by applying a biased voltage to the substrate.

4. The method of claim 1, wherein the forming of the upper magnetic layer pattern is performed by an ion etching process using low-mass species.

5. The method of claim 4, wherein the forming of the upper magnetic layer pattern is performed by an ion etching process using low-mass species of H₂, He, Ne, or N₂.

6. The method of claim 5, wherein the forming of the upper magnetic layer pattern is performed by etching the upper magnetic layer using the insulation layer as an etch stop layer.

7. The method of claim 1, wherein the lower magnetic layer has a thickness in a range from about 1 Å to about 40 Å.

8. The method of claim 1, wherein the insulation layer has a thickness in a range from about 1 Å to about 30 Å.

9. The method of claim 1, wherein, in the operation of forming the upper magnetic layer pattern, etch residues are formed on sidewalls of the upper magnetic layer, and in the operation of performing the oxidation process, the etch residues are oxidized to form a sidewall spacer layer on the sidewalls of the upper magnetic layer.

10. The method of claim 9, further comprising removing the sidewall spacer layer by an ion etching process using low-mass species of H₂, He, Ne, or N₂ or a wet etching process.

11. A method of manufacturing a magnetic device, the method comprising:
sequentially forming a lower magnetic layer, an insulation layer, and an upper magnetic layer;
forming an upper magnetic layer pattern on the insulation layer by patterning the upper magnetic layer using the insulation layer as an etch stop layer;
forming an isolation layer pattern by transforming portions of the insulation layer and the lower magnetic layer to insulating materials, where the upper magnetic layer pattern is not formed; and
forming an insulation layer pattern and a lower magnetic layer pattern from portions of the insulation layer and the lower magnetic layer under the upper magnetic layer pattern.

12. The method of claim 11, wherein the forming of the upper magnetic layer pattern is performed by an ion etching process using low-mass species of H₂, He, Ne, or N₂.

13. The method of claim 11, wherein the forming of the isolation layer pattern comprises transforming portions of the insulation layer and the lower magnetic layer to insulating materials by performing a directional plasma oxidation process, or a directional plasma nitration process.

14. The method of claim 11, further comprising forming a sidewall spacer layer on sidewalls of the upper magnetic layer pattern by transforming etch residues formed on the sidewalls of the upper magnetic layer to insulating materials during the formation of the upper magnetic layer pattern.

15. The method of claim 14, further comprising removing the sidewall spacer layer by an ion etching process using low-mass species of H₂, He, Ne, or N₂ or a wet etching process.

16. A method of manufacturing a magnetic device, the method comprising:
sequentially forming a lower magnetic layer, an insulation layer, and an upper magnetic layer on a substrate;
forming an upper magnetic layer pattern by patterning the upper magnetic layer until an upper surface of the insulation layer is exposed; and
forming an isolation layer pattern from a first region of the insulation layer and the lower magnetic layer, thereby forming an insulation layer pattern and a lower magnetic layer pattern in a second region of the insulation layer and the lower magnetic layer.

17. The method of claim 16, wherein the second region is under the upper magnetic layer pattern.

18. The method of claim 16, wherein forming the isolation layer pattern comprises performing an oxidation process on the exposed upper surface of the insulation layer.

19. The method of claim 16, wherein forming the isolation pattern comprises performing a nitridation process on the exposed upper surface of the insulation layer.

20. The method of claim 16, further comprising a lower electrode layer before forming the lower magnetic layer,
wherein forming the isolation layer pattern comprises oxidizing or nitriding a portion of the lower electrode layer.
